(19) United States
(12) Patent Application Publication
(10) Pub. No.: US 2022/0173039 A1
(43) Pub. Date: Jun. 2, 2022

(54) SELF-ALIGNED LOW RESISTANCE BURIED POWER RAIL THROUGH SINGLE DIFFUSION BREAK DUMMY GATE

(71) Applicant: QUALCOMM Incorporated, San Diego, CA (US)

(72) Inventors: Bin YANG, San Diego, CA (US); Haining YANG, San Diego, CA (US); Xia LI, San Diego, CA (US)

(21) Appl. No.: 17/107,078

(22) Filed: Nov. 30, 2020

(51) Int. Cl. H01L 23/528; H01L 23/50; H01L 27/092; H01L 27/118

(52) U.S. Cl. CPC H01L 23/5286; H01L 23/50; H01L 2027/11881; H01L 27/11807; H01L 27/092

(57) ABSTRACT

Certain aspects of the present disclosure generally relate to a semiconductor device with a buried power rail (BPR) having decreased resistance and a method of fabricating such a semiconductor device with a BPR. An example semiconductor device generally includes a substrate, a first transistor structure disposed above the substrate, a second transistor structure disposed above the substrate, and a BPR structure disposed between the first transistor structure and the second transistor structure. The BPR structure generally includes at least two distinguishable portions, which may be a first portion disposed above a second portion, the second portion having a greater width than the first portion.

### BACKGROUND

### Field of the Disclosure

Certain aspects of the present disclosure generally relate to electronic components and, more particularly, a semiconductor device with a buried power rail having reduced power rail resistance.

### Description of Related Art

A continued emphasis in semiconductor technology is to create improved performance semiconductor devices at competitive prices and/or with smaller sizes. This emphasis over the years has resulted in extreme miniaturization of semiconductor devices, made possible by continued advances in semiconductor processes and materials in combination with new and sophisticated device designs. Large numbers of transistors are employed in integrated circuits (ICs) in many electronic devices. For example, components such as central processing units (CPUs), graphics processing units (GPUs), and memory systems each employ a large quantity of transistors for logic circuits and memory devices.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include decreased power rail resistance.

Certain aspects of the present disclosure provide a semiconductor device. The semiconductor device generally includes a substrate, a first transistor structure disposed above the substrate, a second transistor structure disposed above the substrate, and a buried power rail (BPR) structure disposed between the first transistor structure and the second transistor structure. The BPR structure has at least two distinguishable portions: a first portion disposed above a second portion, where the second portion has a greater width than the first portion.

Certain aspects of the present disclosure provide a method for fabricating a semiconductor device. The method generally includes forming a first transistor structure above a substrate, forming a second transistor structure above the substrate, and forming a BPR structure disposed between the first transistor structure and the second transistor structure. The BPR structure include at least two distinguishable portions: a first portion disposed above a second portion, where the second portion has a greater width than the first portion

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is an isometric view of a semiconductor device with a buried power rail, in accordance with certain aspects of the present disclosure.

FIGS. 2A and 2B are cross-sectional views of semiconductor devices having different example implementations of a buried power rail, in accordance with certain aspects of the present disclosure.

FIGS. 3A-3L illustrate example operations for fabricating a semiconductor device having a buried power rail, in accordance with certain aspects of the present disclosure.

FIG. 4 is a flow diagram depicting example operations for fabricating a semiconductor device, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed to a semiconductor device having a buried power rail (BPR) disposed therein. For example, in some cases, the semiconductor device may include a substrate, a first transistor structure disposed above the substrate, a second transistor structure disposed above the substrate, and a BPR structure disposed between the first transistor structure and the second transistor structure. The BPR structure may be configured in a manner to reduce BPR resistance in the semiconductor device, without sacrificing transistor density (e.g., complementary metal-oxide-semiconductor (CMOS) transistor density). For example, the BPR structure may have at least two different widths (e.g., an oval-shaped or tiered BPR structure). According to certain aspects, the BPR structure may include at least two distinguishable portions, such as a first portion disposed above a second portion, where the second portion has a greater width than the first portion.

### Example Semiconductor Device with BPR

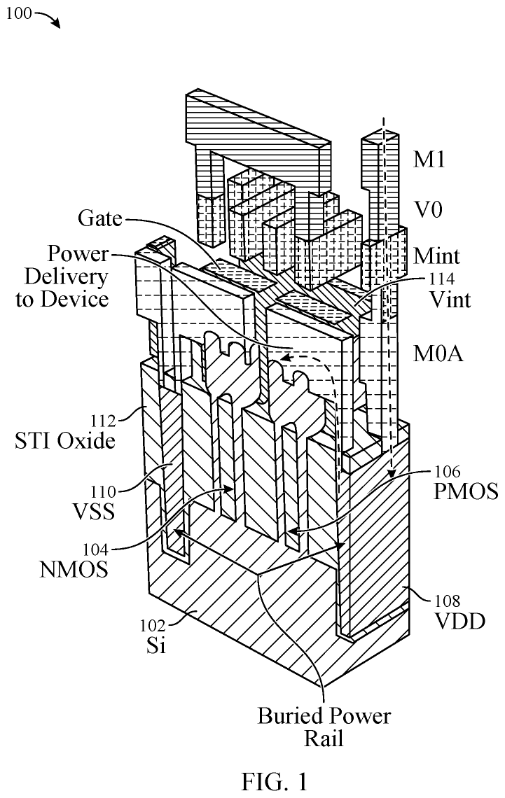

FIG. 1 is an isometric view of a semiconductor device 100 having a buried power rail (BPR). As shown, the semiconductor device 100 may include a complementary metal-oxide-semiconductor (CMOS) structure, which may include an n-type metal-oxide-semiconductor (NMOS) transistor 104 and a p-type metal-oxide-semiconductor (PMOS) transistor 106 disposed above a substrate 102 (e.g., a silicon (Si) substrate). In certain aspects, as illustrated in FIG. 1, the semiconductor device 100 may be a fin field-effect transistor (finFET) device, where each of the NMOS and PMOS transistors 104, 106 is a finFET. For other aspects, the semiconductor device may include only NMOS or only PMOS transistors. A shallow trench isolation (STI) layer 112 may be disposed above the substrate 102, and a portion of the STI layer 112 may extend into the substrate 102, as shown. The STI layer 112 may be composed of an oxide or any other suitable electrically insulating material.

The semiconductor device 100 may also include BPRs 108 and 110 disposed adjacent to the PMOS transistor 106 and the NMOS transistor 104, respectively. Additionally, as shown, each of the BPRs 108 and 110 may be partially disposed within the STI layer 112. Each of the BPRs 108, 110 may be configured to deliver power to the PMOS transistor 106 and/or the NMOS transistor 104. Each of the NMOS and PMOS transistors 104, 106 may include source, drain, and gate regions. As shown, a gate region 114 for each of the NMOS transistor 104 and the PMOS transistor 106 may be disposed in a first metal layer (e.g., M0A). A second metal layer (e.g., Mᵢₙₜ) may be disposed above the first metal layer (e.g., M0A) and coupled with the first metal layer by at least a first via (e.g., Vᵢₙₜ). Additionally, as shown, a third metal layer (e.g., M1) may be disposed above the second metal layer (e.g., Mᵢₙₜ) and coupled to the second metal layer by at least a second via (e.g., V0). This network of connections, as shown, may provide a power supply to the CMOS structure through the BPRs 108, 110.

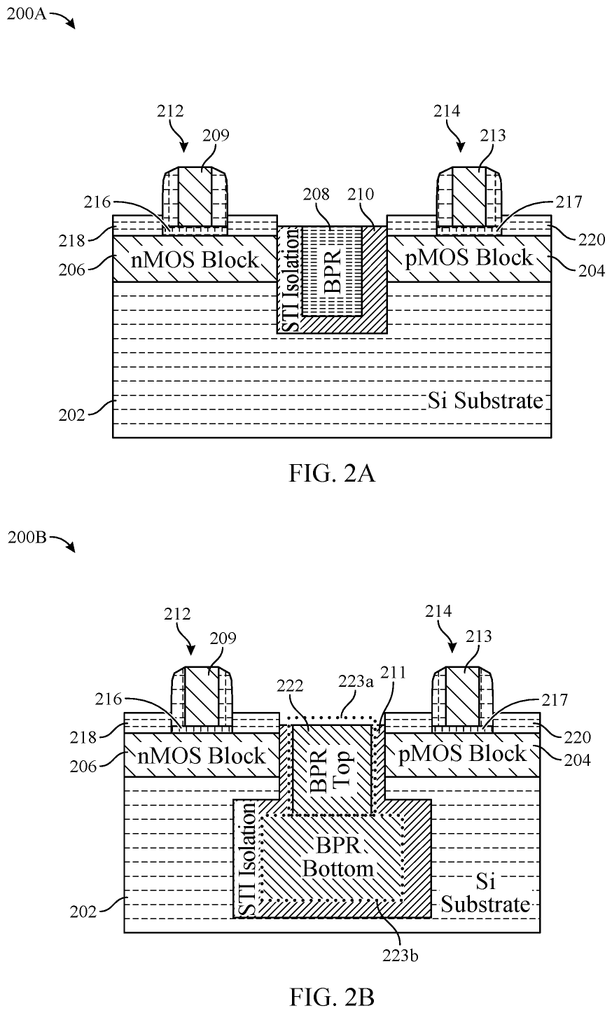

FIG. 2A is a cross-sectional view of a semiconductor device 200A with an example BPR implementation. As shown, the semiconductor device 200A may include a BPR 208 disposed within an STI layer 210 and above a substrate 202. In some cases, the substrate 202 may be a silicon substrate. In certain aspects, the BPR 208 may extend into a portion of the substrate 202. In some cases, the BPR 208 may be composed of a conductive material, such as copper (Cu), tungsten (W), or any other suitable conductive metal. For certain aspects, the BPR 208 may have a generally rectangular, round, or oval shape.

Furthermore, the semiconductor device 200A may include an NMOS transistor 212 and a PMOS transistor 214 disposed on either side of the BPR 208, as shown. Each of the NMOS and PMOS transistors 212, 214 may be disposed above the substrate 202. The NMOS transistor 212 may include a gate 209 disposed between source/drain regions 218, each of which may be disposed above a semiconductor region 206. In certain aspects, the semiconductor region 206 may comprise an n-doped semiconductor material (e.g., at least a portion of an n-doped semiconductor fin). The NMOS transistor 212 may further include an oxide layer 216 disposed between the gate 209 and the semiconductor region 206. Similarly, the PMOS transistor 214 may include a gate 213 disposed between source/drain regions 220, each of which may be disposed above a semiconductor region 204. In certain aspects, the semiconductor region 204 may comprise a p-doped semiconductor material (e.g., at least a portion of a p-doped semiconductor fin). The PMOS transistor 214 may further include an oxide layer 217 disposed between the gate 213 and the semiconductor region 204. In certain aspects, the NMOS transistor 212 and the PMOS transistor 214 may be finFETs, as depicted in FIG. 2A.

Conventionally, metal routing and power rail congestion within semiconductor devices may serve as a limitation to fabricating CMOS devices beyond 5 nm. Some BPR designs, similar to that of FIG. 2A, may be implemented to help relieve the power rail congestion issue for semiconductor devices at the 5 nm technology node. However, such a BPR 208 may not be self-aligned to either gate 209 or gate 213. As a result, the BPR 208 may occupy an inefficient amount of space relative to the width and overall conductivity of the BPR 208. As shown in FIG. 2A, the relatively narrow shape of the BPR 208 may also cause the BPR 208 to have relatively high internal resistance. The relatively high resistance of the BPR 208 fabricated by conventional approaches may prevent achieving the full potential benefits of the BPR.

Accordingly, aspects of the present disclosure provide semiconductor devices and techniques for fabricating such semiconductor devices with a BPR with an enlarged size (e.g., an increased bottom width) to reduce overall resistance of the BPR. In certain aspects, techniques described herein provide advantages for significantly reducing BPR resistance up to, or even more than, 50% as compared to conventional BPRs. Furthermore, processes (e.g., middle-of-line (MOL) processes) described herein may provide for construction of a semiconductor device with enhanced power delivery without impacting, or at least without significantly decreasing, CMOS density or increasing manufacturing cost. In certain aspects, techniques described in the present disclosure may be scaled below 5 nm.

### Example Semiconductor Device with Reduced Resistance BPR

Certain aspects of the present disclosure provide a semiconductor device. The semiconductor device may include a substrate, a first transistor structure disposed above the substrate, a second transistor structure disposed above the substrate, and a buried power rail (BPR) structure disposed between the first transistor structure and the second transistor structure. The BPR structure may be configured in a manner to lower BPR resistance in the semiconductor device, without sacrificing transistor density. For example, the BPR structure may have at least two different widths (e.g., an oval-shaped or tiered BPR structure). In certain aspects, the BPR structure may include at least two distinguishable portions, such as a first portion disposed above a second portion. In some cases, the second portion may have a greater width than the first portion.

FIG. 2B is a cross-sectional view of a semiconductor device 200B with a buried power rail structure, in accordance with certain aspects presented herein. As shown, the structure of the semiconductor device 200B may be similar to that of the semiconductor device 200A of FIG. 2A; however the semiconductor device 200B may include a BPR 222 with a structure different from that of the BPR 208, as explained below.

As shown in FIG. 2B, the BPR 222 may be disposed between the NMOS transistor 212 and the PMOS transistor 214. Further, as shown, the BPR 222 may be disposed adjacent to an STI layer 211 and may extend further into the substrate 202 than the BPR 208 of FIG. 2A. Additionally, as shown, the STI layer 211 may have a different shape than the STI layer 210 of FIG. 2A, for example, to conform to the different shape of the BPR 222. In certain aspects, a bottom portion 223b of the BPR 222 may be wider than a top portion 223a of the BPR 222, which may provide for a larger cross-sectional area to decrease resistance and increase current through the BPR 222. The BPR 222 may include a tiered structure in which the bottom portion 223b of the BPR 222 comprises a first tier and the top portion 223a of the BPR 222 comprises a second tier. In certain aspects, the top portion 223a of the BPR 222 may extend to a greater depth into the substrate 202 than a bottom of the NMOS transistor 212 and/or PMOS transistor 214 (e.g., defined by the semiconductor region 206 and semiconductor region 204, respectively). Furthermore, the bottom portion 223b of the BPR 222 may be disposed in the substrate 202, at least partially, beneath at least one of the NMOS transistor 212 or the PMOS transistor 214. Additionally, in some cases, a width of the bottom portion 223b of the BPR 222 may be wider than a distance between the NMOS transistor 212 and the PMOS transistor 214, as shown. An upper surface of the bottom portion 223b of the BPR 222 may be located at a greater depth than a bottom surface (or a channel surface) of the NMOS transistor 212 and/or PMOS transistor 214 (e.g., than a bottom level of doping for an n-type fin or a p-type fin). In certain aspects, the BPR 222 may be composed of a suitable conductive material, such as tungsten, titanium nitride, or a combination thereof. The large volume of the BPR 222 due to the greater depth and/or to the increased width of the bottom portion 223b will decrease the overall resistance of the BPR 222 of FIG. 2B, compared to the BPR 208 of FIG. 2A.

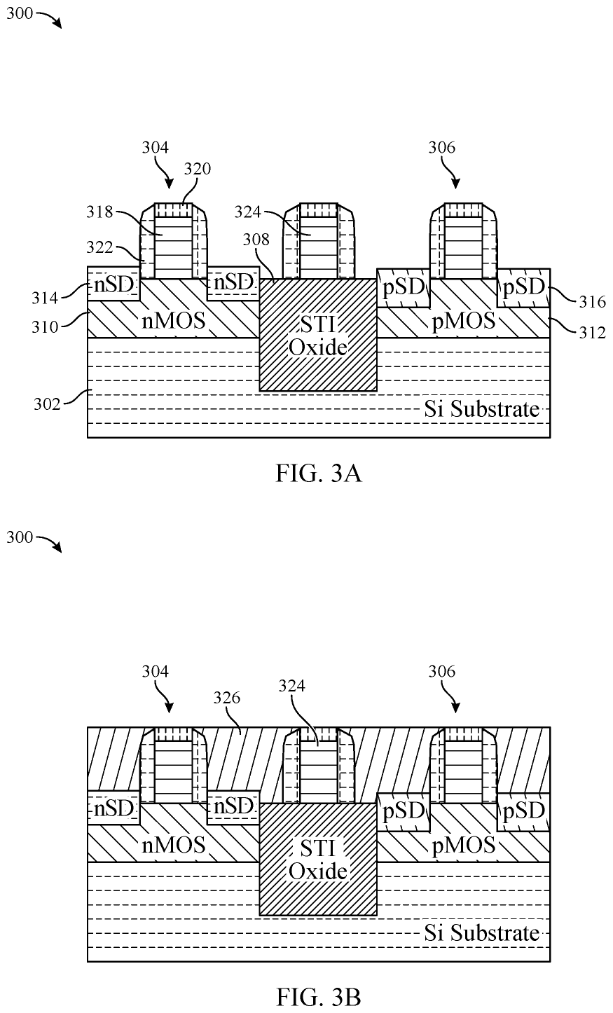

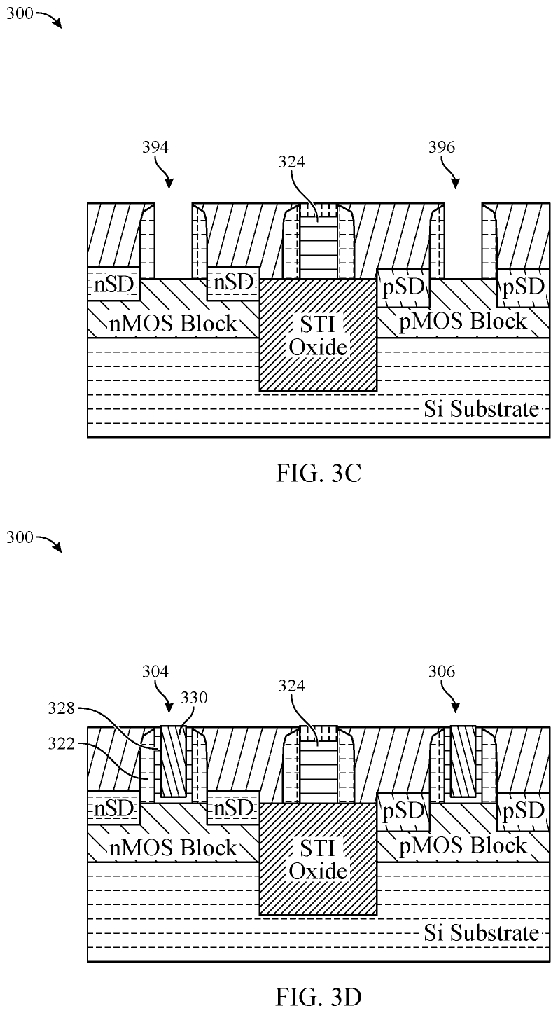

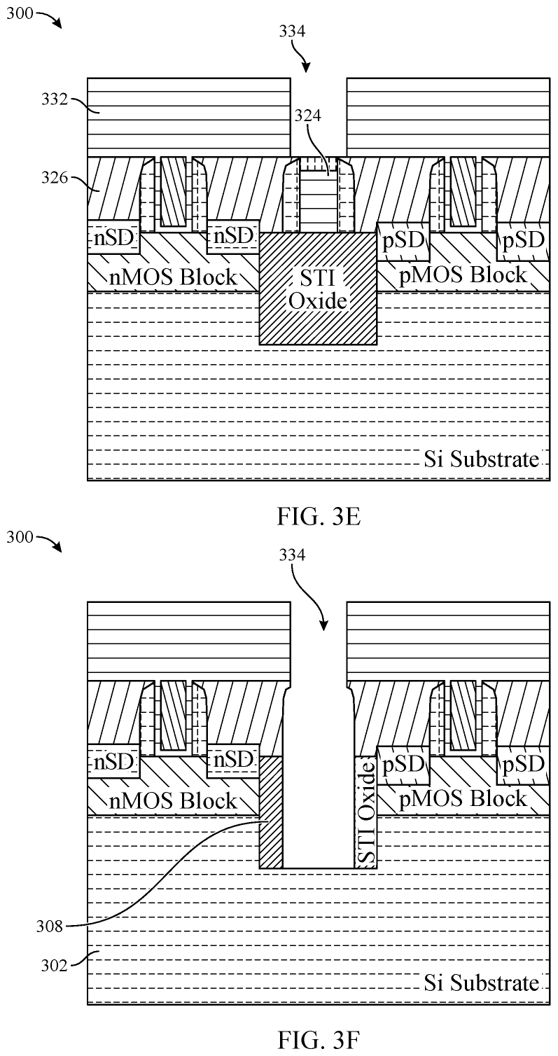

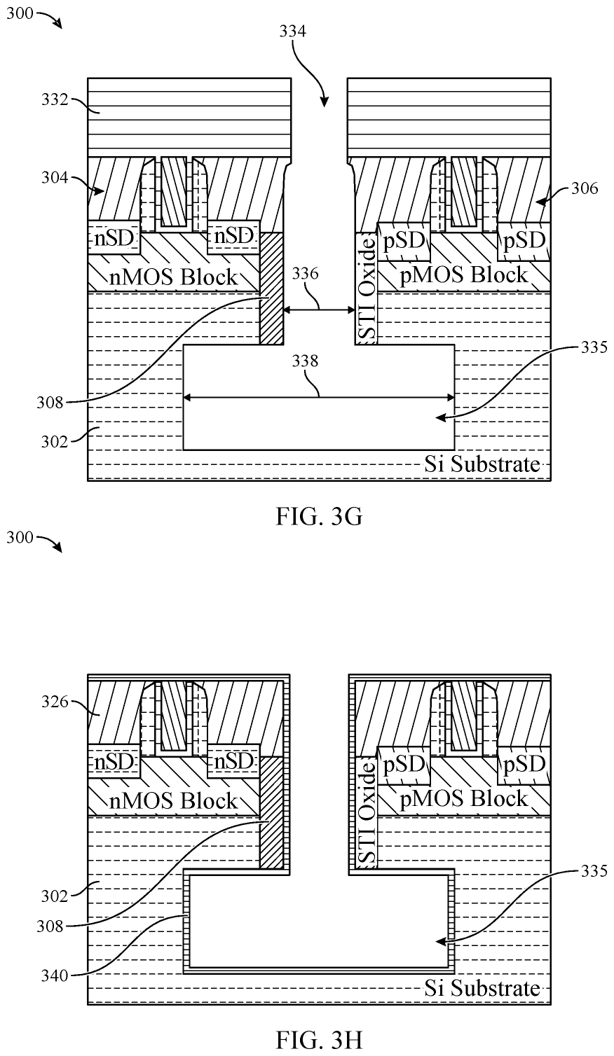

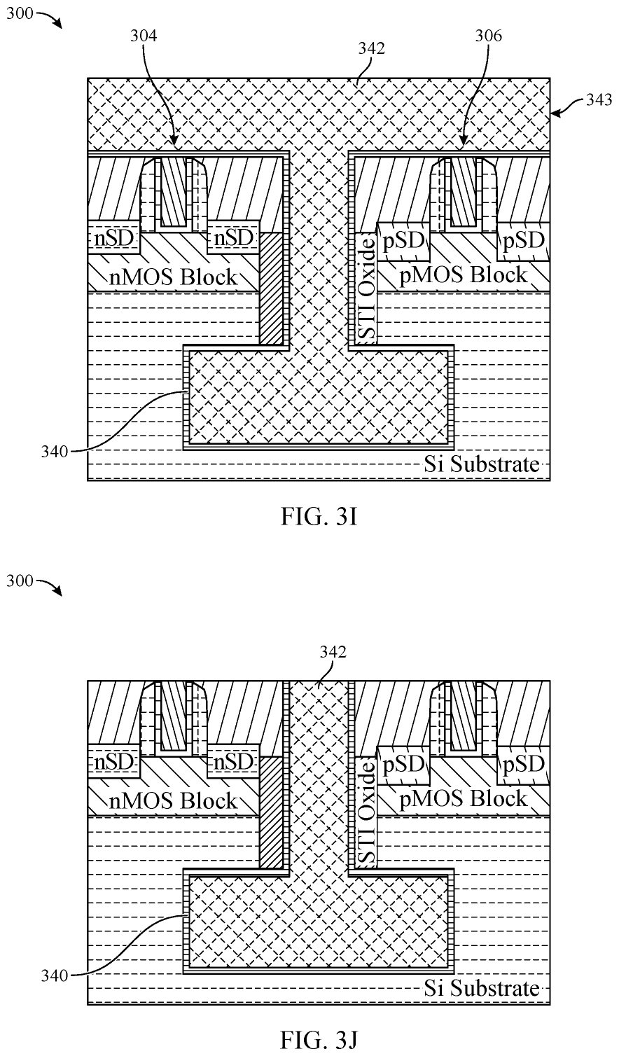

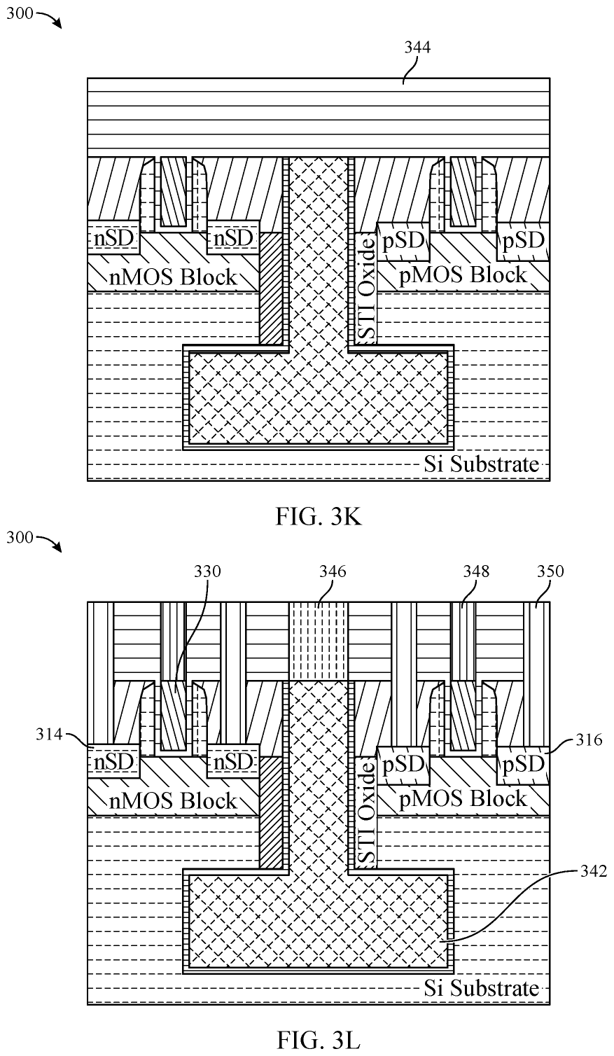

FIGS. 3A-3L illustrate example operations for fabricating a semiconductor device having a buried power rail. In some cases, the semiconductor device may be an example of the semiconductor device 200B of FIG. 2B described above.

For example, as shown in FIG. 3A, the operations for fabricating the semiconductor device having the buried power rail may begin with a workpiece 300 having a finFET or gate-all-around (GAA) CMOS structure including a substrate 302, above which transistors may be formed. For example, an NMOS transistor 304 and a PMOS transistor 306 may be formed above the substrate 302. For other aspects, the workpiece 300 may include only n-type transistors or only p-type transistors. An STI layer 308 may be formed between the NMOS transistor 304 and the PMOS transistor 306. In some cases, the STI layer 308 may have a width of about 20 nm and may be composed of an oxide material or any other suitable electrically insulative material.

In certain aspects, the NMOS transistor 304 and the PMOS transistor 306 may include semiconductor regions 310 and 312, respectively, as well as source/drain regions 314 and 316, respectively. The semiconductor regions 310 and 312 may be composed of a semiconductor material, such as silicon (Si) or silicon germanium (SiGe), and be approximately 5-10 nm wide and 40 nm tall. In some cases, the semiconductor region 310 may be composed of an n-doped semiconductor material, while the semiconductor region 312 may be composed of a p-doped semiconductor material. Further, in some cases, each of the source/drain regions 314 and source/drain regions 316 may be epitaxially grown and composed of a material, such as phosphorous-doped silicon (Si:P) or SiGe, respectively. Additionally, each of the NMOS and PMOS transistors 304, 306 may include a dummy gate 318 including a hard mask 320 disposed above the dummy gate 318. Further, as shown, the dummy gate 318 and hard mask 320 may be disposed between spacers 322. In certain aspects, the dummy gate 318 may be composed of a material such as polycrystalline silicon (poly-Si) and may have a height of approximately 50 nm and a width of 5-20 nm. In certain aspects, the hard mask 320 may be composed of a material such as silicon nitride (Si₃N₄) and may have a width of approximately 10 nm. In some cases, the spacers 322 may be composed of a material such as silicon nitride or an oxide and have a thickness between 2-10 nm.

Furthermore, as shown, a dummy gate 324 may be formed above the STI layer 308. In certain aspects, the dummy gate 324 may be of similar construction as the dummy gate 318 of the NMOS transistor 304 and the PMOS transistor 306. In certain aspects, the dummy gate 324 may be a single diffusion break (SDB) dummy gate.

As shown in FIG. 3B, a dielectric layer 326 may be formed on top of the workpiece 300 (i.e., above upper surfaces of the workpiece 300). In certain aspects, the dielectric layer 326 may be adjacent to and surround lateral surfaces of each of the dummy gates 318 of the NMOS transistor 304 and the PMOS transistor 306, as well the dummy gate 324. Furthermore, in certain aspects, the dielectric layer 326 may undergo chemical-mechanical planarization (CMP) such that the top surface of the dielectric layer 326 is flush with a top surface of each of the dummy gates 318 and 324, as shown. In some cases, the dielectric layer 326 may be composed of an oxide or any other suitable electrically insulative material.

As shown in FIG. 3C, the dummy gate 318 and the hard mask 320 may be removed from each of the NMOS and PMOS transistors 304, 306, forming respective wells 394, 396. This removal may be part of a replacement metal gate (RMG) process, for example. In certain aspects, the removal of the dummy gates 318 and the hard masks 320 may be accomplished via photolithography and wet chemical etching. The dummy gate 324 may remain, as depicted.

As shown in FIG. 3D, an oxide layer 328 may be formed on exposed surfaces of each of the wells 394, 396 of the NMOS and PMOS transistors 304, 306. Thereafter, a metal gate 330 may be disposed on exposed surfaces of the oxide layer 328, filling each respective well of the NMOS transistor 304 and the PMOS transistor 306. In certain aspects, the metal gate 330 may be a high-κ metal gate. The metal gate 330 may further undergo CMP to ensure a top surface of the metal gate 330 is flush with other upper surfaces of the workpiece 300.

As shown in FIG. 3E, a photoresist layer 332 may be formed above portions of the workpiece 300. In certain aspects, the photoresist layer 332 may be formed to have a trench 334 in the middle of the photoresist layer 332 such that the dummy gate 324 is exposed (e.g., such that the photoresist layer 332 does not cover the dummy gate 324).

Thereafter, as shown in FIG. 3F, the dummy gate 324 may be removed by, for example, wet chemical etching, which may enlarge the trench 334. Once the dummy gate 324 is removed, a portion of the STI layer 308 that was underneath the dummy gate 324 may be etched (e.g., dry etched) down to the substrate 302. In certain aspects, the space left by the removed dummy gate 324 (e.g., the enlarged trench 334) self-aligns the etching of the STI layer 308. In certain aspects, such removal of the dummy gate 324 and the portion of the STI layer 308 may allow for improved utilization of the trench 334 for a BPR.

As shown in FIG. 3G, a portion of the substrate 302 below the trench 334 may then be etched (e.g., isotropically etched) to form a cavity 335 wider than the trench 334. As shown, the enlarged trench 334 may have a first width 336 spanning between two portions of the STI layer 308, while the cavity 335 may have a second width 338 that is larger than the first width 336. In certain aspects, one or more portions of the cavity 335 may be disposed below at least one of the NMOS transistor 304 or the PMOS transistor 306. In FIG. 3G, the cavity 335 extends below both the NMOS transistor 304 and the PMOS transistor 306.

Thereafter, as shown in FIG. 3H, the photoresist layer 332 may be removed (e.g., via stripping), and an oxide layer 340 may be formed on exposed surfaces of the dielectric layer 326, the substrate 302, and the STI layer 308 (e.g., within the trench 334 and cavity 335). In some cases, the oxide layer 340 may be a conformal oxide isolation layer, conforming to the shape of the exposed surfaces.

As shown in FIG. 3I, a conductive material 342 may then be deposited on exposed surfaces of the oxide layer 340, filling in the trench 334 and the cavity 335 and forming a layer 343 above the NMOS transistor 304 and the PMOS transistor 306. In certain aspects, the conductive material 342 may comprise tungsten, titanium nitride, a suitable combination thereof, or any other suitable metal or metal alloy.

Thereafter, as shown in FIG. 3J, the layer 343 of the conductive material 342 may be removed (e.g., etched), and portions of the oxide layer 340 disposed above the NMOS transistor 304 and the PMOS transistor 306 may be removed, as well. In certain aspects, the conductive material 342 and the portion of the oxide layer 340 may undergo CMP. In certain aspects, the remaining portion of the conductive material 342 (e.g., formed in the trench 334 and cavity 335) may constitute a BPR.

Thereafter, as illustrated in FIG. 3K, a dielectric layer 344 may be formed on top of the workpiece 300. In certain aspects, the dielectric layer 344 may be composed of an oxide material and may have a height of approximately 30 nm.

As shown in FIG. 3L, the dielectric layer 344 may subsequently be etched and filled with a conductive material (e.g., a metal or metal alloy) to form one or more BPR contacts 346, gate contacts 348, and source/drain contacts 350. For example, as shown, the BPR contact 346 may be disposed adjacent to the conductive material 342. Furthermore, in certain aspects, the gate contacts 348 may be disposed adjacent to the metal gates 330. Additionally, each of the source/drain contacts 350 may be disposed adjacent to one of the source/drain regions 314 and 316. In certain aspects, the contacts 346, 348, 350 may be composed of copper, tungsten, or any suitable material to provide an ohmic contact.

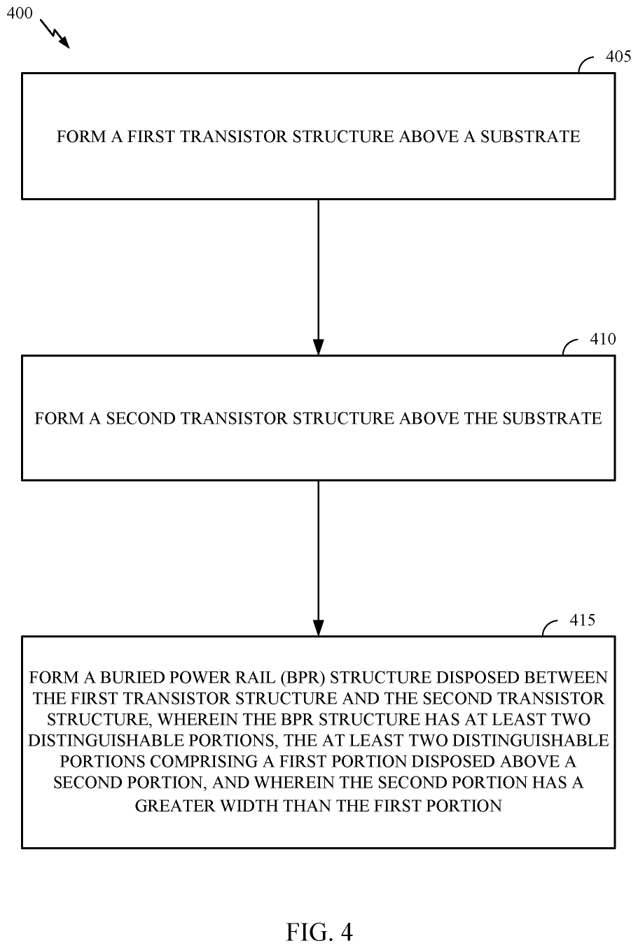

FIG. 4 is a flow diagram of example operations 400 for fabricating an example semiconductor device (e.g., the semiconductor device 200B depicted in FIG. 2B), in accordance with certain aspects of the present disclosure. In some cases, the operations 400 may be performed by a fabrication facility, for example.

The operations 400 may begin at block 405 with the facility forming a first transistor structure (e.g., the PMOS transistor 214 or 306) above a substrate (e.g., the substrate 202 or 302).

At block 410, the facility forms a second transistor structure (e.g., the NMOS transistor 212 or 304) above the substrate.

At block 415, the facility forms a BPR structure (e.g., the BPR 222) disposed between the first transistor structure and the second transistor structure. In this case, the BPR structure has at least two distinguishable portions, the at least two distinguishable portions including a first portion (e.g., the top portion 223a) disposed above a second portion (e.g., the bottom portion 223b). The second portion has a greater width (e.g., the second width 338) than the first portion (e.g., the first width 336).

In certain aspects, forming the BPR structure at block 415 may include disposing a dummy gate (e.g., the dummy gate 324) above a dielectric material (e.g., the STI layer 308) disposed between the first transistor structure and the second transistor structure. For example, the dummy gate may be a single diffusion break (SDB) dummy gate. In some cases, forming the BPR structure at block 415 may further include applying a mask (e.g., the photoresist layer 332) above the first transistor structure and the second transistor structure, where the mask exposes the dummy gate above the dielectric material, and removing the dummy gate and a portion of the dielectric material. In this case, the dummy gate may be removed using wet chemical etching, stopping at the dielectric material, and/or the portion of the dielectric material may be removed using dry etching of the dielectric material. In some cases, a space left by the removed dummy gate may self-align the dry etching of the dielectric material. In some cases, the dry etching may stop at the substrate.

In certain aspects, forming the BPR structure at block 415 may involve forming a cavity (e.g., the cavity 335) in the substrate after removing the dummy gate and the portion of the dielectric material. In some cases, the cavity may be formed by isotropic etching, such that a width of the cavity in the substrate is greater than a width of a trench (e.g., the trench 334) that is formed by removing the dummy gate and the portion of the dielectric material. In some cases, forming the BPR structure may further entail depositing a conformal insulative layer (e.g., the oxide layer 340) to line the cavity in the substrate and a trench formed by removing the dummy gate and the portion of the dielectric material, and depositing a conductive material (e.g., the conductive material 342) in the trench and the cavity in the substrate to form the BPR structure. In this example, the conductive material in the trench may form the first portion of the BPR structure, and the conductive material in the cavity in the substrate may form the second portion of the BPR structure.

Certain aspects of the present disclosure generally relate to a semiconductor device having a buried power rail (BPR) with at least two different widths (e.g., a tiered or oval-shaped BPR structure) in an effort to significantly reduce BPR resistance compared to conventional BPRs (e.g., ≤50% resistance). For certain aspects, a bottom portion of the BPR structure may extend beneath a bottom level of a dielectric layer (e.g., an STI region) and into the substrate for increased overall BPR volume and, hence, lower resistance. Certain aspects of the present disclosure also generally relate to a method of fabricating a semiconductor device having a BPR, which may involve using a dummy gate (e.g., an SDB gate) as a self-aligning mask and etching (e.g., isotropically etching) into the substrate.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A semiconductor device comprising:
a substrate;
a first transistor structure disposed above the substrate;
a second transistor structure disposed above the substrate; and
a buried power rail (BPR) structure disposed between the first transistor structure and the second transistor structure, wherein:
the BPR structure comprises a tiered BPR structure having at least two distinguishable portions, the at least two distinguishable portions comprising a first portion disposed above a second portion;
the second portion has a greater width than the first portion;
the first portion is a first rectangular layer of the tiered BPR structure; and
the second portion is a second rectangular layer of the tiered BPR structure.

2-3. (canceled)

4. The semiconductor device of claim 1, wherein the second portion of the BPR structure is disposed in a cavity of the substrate.

5. The semiconductor device of claim 1, wherein an upper surface of the second portion of the BPR structure is disposed at a greater depth in the semiconductor device than a bottom surface of the first transistor structure and a bottom surface of the second transistor structure.

6. The semiconductor device of claim 5, wherein the first portion is disposed adjacent to the first transistor structure and to the second transistor structure.

7. The semiconductor device of claim 1, wherein the width of the second portion of the BPR structure is greater than a distance between a first semiconductor material of the first transistor structure and a second semiconductor material of the second transistor structure.

8. The semiconductor device of claim 1, wherein the BPR structure comprises at least one of tungsten or titanium nitride.

9. The semiconductor device of claim 1, further comprising a dielectric material disposed between the BPR structure and at least one of the first transistor structure or the second transistor structure.

10. The semiconductor device of claim 1, wherein at least one of the first transistor structure or the second transistor structure comprises a fin field-effect transistor (finFET) structure.

11. The semiconductor device of claim 1, wherein the first transistor structure comprises a p-type metal-oxide-semiconductor (PMOS) transistor and wherein the second transistor structure comprises an n-type metal-oxide-semiconductor (NMOS) transistor.

12. The semiconductor device of claim 1, wherein a bottom surface of the first portion of the BPR structure is disposed at a greater depth in the semiconductor device than a bottom surface of the first transistor structure and a bottom surface of the second transistor structure.

13. A method of fabricating a semiconductor device, the method comprising:
forming a first transistor structure above a substrate;
forming a second transistor structure above the substrate; and
forming a buried power rail (BPR) structure disposed between the first transistor structure and the second transistor structure, wherein:
the BPR structure comprises a tiered BPR structure having at least two distinguishable portions, the at least two distinguishable portions comprising a first portion disposed above a second portion;
the second portion has a greater width than the first portion;
the first portion is a first rectangular layer of the tiered BPR structure; and
the second portion is a second rectangular layer of the tiered BPR structure.

14. The method of claim 13, wherein forming the BPR structure comprises disposing a dummy gate above a dielectric material disposed between the first transistor structure and the second transistor structure.

15. The method of claim 14, wherein the dummy gate is a single diffusion break (SDB) dummy gate.

16. The method of claim 14, wherein forming the BPR structure further comprises:
applying a mask above the first transistor structure and the second transistor structure, wherein the mask exposes the dummy gate above the dielectric material; and
removing the dummy gate and a portion of the dielectric material.

17. The method of claim 16, wherein removing the dummy gate and the portion of the dielectric material comprises:
removing the dummy gate using wet chemical etching, wherein the wet chemical etching stops at the dielectric material; and
removing the portion of the dielectric material using dry etching of the dielectric material, wherein a space left by the removed dummy gate self-aligns the dry etching of the dielectric material and wherein the dry etching stops at the substrate.

18. The method of claim 16, wherein forming the BPR structure further comprises forming a cavity in the substrate after removing the dummy gate and the portion of the dielectric material.

19. The method of claim 18, wherein forming the cavity in the substrate comprises isotropic etching, such that a width of the cavity in the substrate is greater than a width of a trench formed by removing the dummy gate and the portion of the dielectric material.

20. The method of claim 18, wherein forming the BPR structure further comprises:
depositing a conformal insulative layer to line the cavity in the substrate and a trench formed by removing the dummy gate and the portion of the dielectric material; and
depositing a conductive material in the trench and the cavity in the substrate to form the BPR structure, wherein the conductive material in the trench forms the first portion of the BPR structure and wherein the conductive material in the cavity in the substrate forms the second portion of the BPR structure.

21. A method of fabricating a semiconductor device, the method comprising:
forming a first transistor structure above a substrate;
forming a second transistor structure above the substrate; and
forming a buried power rail (BPR) structure disposed between the first transistor structure and the second transistor structure, wherein:
the BPR structure has at least two distinguishable portions, the at least two distinguishable portions comprising a first portion disposed above a second portion;
the second portion has a greater width than the first portion; and
forming the BPR structure comprises:
disposing a dummy gate above a dielectric material disposed between the first transistor structure and the second transistor structure;
applying a mask above the first transistor structure and the second transistor structure, wherein the mask exposes the dummy gate above the dielectric material; and
removing the dummy gate and a portion of the dielectric material.

22. The semiconductor device of claim 1, wherein:
the first rectangular layer of the tiered BPR structure is directly adjacent to the second rectangular layer of the tiered BPR structure; and
a longitudinal axis of the first rectangular layer of the tiered BPR structure is parallel to a longitudinal axis of the second rectangular layer of the tiered BPR structure.
